(19) United States
(12) Patent Application Publication
(10) Pub. No.: US 2024/0243177 A1
(43) Pub. Date: Jul. 18, 2024

(54) SEMICONDUCTOR DEVICE AND METHOD OF MANUFACTURING THE SEMICONDUCTOR DEVICE

(71) Applicant: Samsung Electronics Co., Ltd., Suwon-si (KR)

(72) Inventors: Joonyong KIM, Suwon-si (KR); Jaejoon OH, Suwon-si (KR); Boram KIM, Suwon-si (KR); Jongseob KIM, Suwon-si (KR); Junhyuk PARK, Suwon-si (KR); Sunkyu HWANG, Suwon-si (KR); Injun HWANG, Suwon-si (KR)

(73) Assignee: Samsung Electronics Co., Ltd., Suwon-si (KR)

(21) Appl. No.: 18/347,223

(22) Filed: Jul. 5, 2023

(30) Foreign Application Priority Data
Jan. 16, 2023 (KR) 10-2023-0006307

(51) Int. Cl. H01L 29/20; H01L 29/417; H01L 29/66; H01L 29/778

(52) U.S. Cl. CPC H01L 29/2003; H01L 29/41766; H01L 29/66462; H01L 29/7786

(57) ABSTRACT

A method of manufacturing a semiconductor device according to various example embodiments includes forming a buffer layer and a first semiconductor layer on a substrate, forming a recess by etching the first semiconductor layer, sequentially forming a second semiconductor layer and a third semiconductor layer on the first semiconductor layer in which the recess is formed, and forming a source and a drain respectively in contact with both sides of the first semiconductor layer, the second semiconductor layer, and the third semiconductor layer.

### CROSS-REFERENCE TO RELATED APPLICATION

This application is based on and claims priority under 35 U.S.C. § 119 to Korean Patent Application No. 10-2023-0006307, filed on Jan. 16, 2023, in the Korean Intellectual Property Office, the disclosure of which is incorporated by reference herein in its entirety.

### BACKGROUND

Various example embodiments relate to a semiconductor device and/or to a method of manufacturing the semiconductor device.

A power semiconductor is a key component that converts, stores, distributes, and/or controls power entering an electronic device. Research and development have been conducted to increase conversion efficiency by using a gallium nitride semiconductor, which is a new material for power semiconductors. Recently, efforts have been made to reduce the channel resistance of a gallium nitride device by using a multi-channel structure. A representative multi-channel gate structure include a tri-gate and a FinFET structure. In the case of such technology, it may be difficult to perform a fast and/or stable gate operation due to a trap site that is caused by damage generated during a recess in a channel region.

### SUMMARY

Provided is a semiconductor device in which the generation of a trap site is wholly or at least partially suppressed and/or a method of manufacturing the semiconductor device.

Alternatively or additionally, provided is a semiconductor device capable of more easily controlling a gate and/or a method of manufacturing the semiconductor device.

Additional aspects will be set forth in part in the description which follows and, in part, will be apparent from various descriptions, and/or may be learned by practice of various example embodiments.

According to some example embodiments, a method of manufacturing a semiconductor device, the method includes forming a first semiconductor layer on a substrate, forming a recess by at least partially etching the first semiconductor layer, sequentially forming a second semiconductor layer and a third semiconductor layer that are on the first semiconductor layer in which the recess is formed, and forming a source and a drain respectively in contact with first and second sides of the first semiconductor layer, the second semiconductor layer, and the third semiconductor layer.

Alternatively or additionally according to various example embodiments, a semiconductor device includes a substrate, a first semiconductor layer on the substrate and defining a recess, a second semiconductor layer on the first semiconductor layer, a third semiconductor layer on the second semiconductor layer, a gate semiconductor layer on the third semiconductor layer, and a source and a drain respectively contacting first and second sides of the first semiconductor layer, the second semiconductor layer, and the third semiconductor layer, wherein a channel may be formed between the first semiconductor layer and the second semiconductor layer and between the second semiconductor layer and the third semiconductor layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a cross-sectional view of a semiconductor device according to various example embodiments;

FIG. 1B is a schematic diagram illustrating an arrangement relationship between a source, a drain and a recess of a semiconductor device according to various example embodiments;

FIG. 2A is a cross-sectional view of a semiconductor device according to another embodiment;

FIG. 2B is a schematic diagram illustrating an arrangement relationship between a source, a drain and a recess of a semiconductor device according to various example embodiments;

FIGS. 3A to 3F are cross-sectional views illustrating a method of manufacturing a semiconductor device according to various example embodiments;

FIGS. 4A to 4E are cross-sectional views illustrating a method of manufacturing a semiconductor device according to another embodiment; and

FIGS. 5A and 5B are diagrams illustrating a method of manufacturing a semiconductor device according to another embodiment.

### DETAILED DESCRIPTION

Reference will now be made in detail to various embodiments, examples of which are illustrated in the accompanying drawings, wherein like reference numerals refer to like elements throughout. In this regard, example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and/or a method of manufacturing the semiconductor device will be described with reference to the accompanying drawings.

In the drawings, like reference numerals refer to like elements throughout, and sizes of elements in the drawings may be exaggerated for clarity and convenience of explanation. The embodiments of the disclosure are capable of various modifications and may be embodied in many different forms.

When an element or layer is referred to as being “on” or “above” another element or layer, the element or layer may be directly on another element or layer or intervening elements or layers. The singular forms include the plural forms unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Connections or connection members of lines between components shown in the drawings illustrate functional connections and/or physical or circuit connections, and the connections or connection members may be represented by replaceable or additional various functional connections, physical connections, or circuit connections in an actual apparatus.

All examples or example terms are simply used to explain in detail the technical scope of the disclosure, and thus, the scope of the disclosure is not limited by the examples or the example terms as long as it is not defined by the claims.

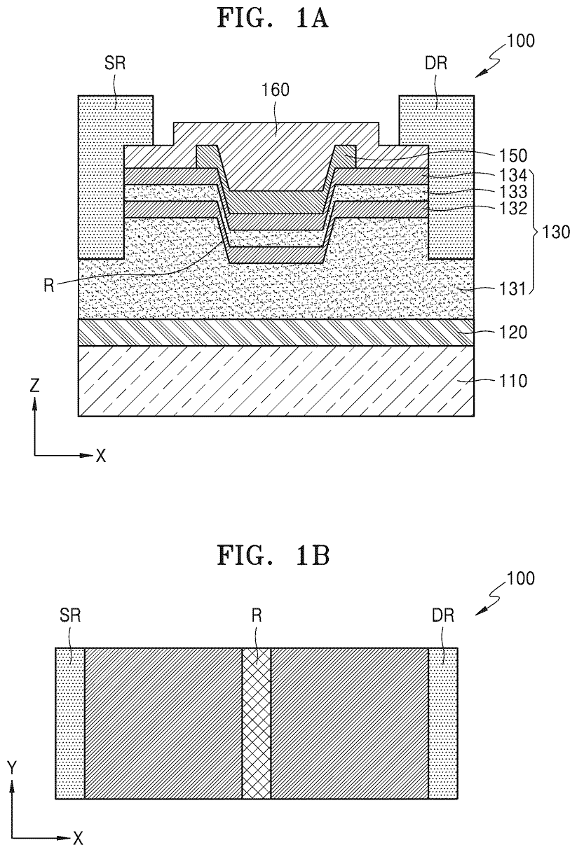

FIG. 1A is a cross-sectional view of a semiconductor device 100 according to various example embodiments.

Referring to FIG. 1A, the semiconductor device 100 includes a first semiconductor layer 131, a second semiconductor layer 132, a third semiconductor layer 133, a fourth semiconductor layer 134, and a gate semiconductor layer 150. The first semiconductor layer 131, the second semiconductor layer 132, the third semiconductor layer 133, and the fourth semiconductor layer 134 may be expressed as a channel layer 130. A buffer layer 120 may be provided on the substrate 110, and a channel layer 130 may be formed on the buffer layer 120.

The substrate 110 may include, for example, one or more of sapphire, silicon (Si), silicon carbide (SiC), or gallium nitride (GaN). The buffer layer 120 may be formed on the substrate 110. The substrate 110 and the buffer layer 120 are layers used as needed or as desired in a manufacturing process, and may be removed from the semiconductor device 100 in a final structure. The buffer layer 120 may be omitted, for example, when a difference in lattice constant between a material of the substrate 110 and the channel layer 130 is sufficiently small.

The buffer layer 120 may mitigate the difference in lattice constant and thermal expansion coefficient between the substrate 110 and the channel layer 130 to prevent deterioration of crystallinity of the channel layer 130. The buffer layer 120 may have a single-layer or multi-layer structure including one or more materials selected from the Group III-V materials, for example, nitrides including at least one of Al, Ga, and In. The buffer layer 120 may be AlₓIn_{y}Ga_{1-x-y}N(0≤x≤1, 0≤y≤1, x+y≤1). The buffer layer 120 may have a single-layer or multi-layer structure including, for example, at least one of AlN, GaN, AlGaN, InGaN, AlInN, and AlGaInN.

The channel layer 130 is a layer that may form a channel, e.g. a conductive channel, between a source and a drain. The first semiconductor layer 131 may include GaN. The first semiconductor layer 131 may include a material capable of forming a two-dimensional electron gas (2 DEG) therein. The first semiconductor layer 131 may include or define a recess R. By forming the recess R in the first semiconductor layer 131 before forming the channel, the recess may not be formed after the channel is formed. Through this, it is possible to minimize or reduce the occurrence of and/or impact from a trap site due to damage caused during recessing of the channel region. The recess R may include two inclined side surfaces and a bottom surface between the two side surfaces. The shape of the recess R may be one or more of an inverted trapezoid, a V-shape, or a U-shape. The first semiconductor layer 131 may be an undoped layer or may be a layer doped with an impurity such as but not limited to one or more of boron, carbon, phosphorus, or arsenic.

The second semiconductor layer 132 may be disposed on the first semiconductor layer 131 in which the recess is formed. The second semiconductor layer 132 may include a material capable of forming a two-dimensional electron gas (2 DEG) therein, that may or may not be the same as any material included in the first semiconductor layer 131. The second semiconductor layer 132 may be disposed to have different thicknesses on the side surfaces and the bottom surface of the recess R. A thickness of the second semiconductor layer 132 disposed on the side surface of the recess R may be less than a thickness of the second semiconductor layer 132 disposed on the bottom surface of the recess R. The thickness of the second semiconductor layer 132 disposed on the side surface of the recess R may be greater than or equal to about 25 Å (2.5 nm) and less than or equal to about 150 Å (15 nm), and the thickness of the second semiconductor layer 132 disposed on the bottom surface of the recess R may be about greater than or equal to 50 Å (5 nm) and less than or equal to about 300 Å (30 nm). The second semiconductor layer 132 includes a semiconductor material different from that of the first semiconductor layer 131. The second semiconductor layer 132 may include AlGaN. The second semiconductor layer 132 may be an undoped layer or a layer doped with an impurity that is the same as, or different from, any impurities doped into the first semiconductor layer 131.

The third semiconductor layer 133 may be disposed on the second semiconductor layer 132. The third semiconductor layer 133 may include a material capable of forming a two-dimensional electron gas (2 DEG) therein that may or may not be the same as any material included in the first semiconductor layer 131 and/or the second semiconductor layer 132. The third semiconductor layer 133 may be disposed to have different thicknesses on the side surface and the bottom surface of the recess R. The thickness of the third semiconductor layer 133 disposed on the side surface of the recess R may be less than the thickness of the third semiconductor layer 133 disposed on the bottom surface of the recess R. The thickness of the third semiconductor layer 133 disposed on the side surface of the recess R may be greater than or equal to about 25 Å (2.5 nm) and less than or equal to about 150 Å (15 nm), and the thickness of the third semiconductor layer 133 disposed on the bottom surface of the recess R may be about greater than or equal to 50 Å (5 nm) and less than or equal to 300 Å (30 nm). The third semiconductor layer 133 includes the same semiconductor material as the first semiconductor layer 131. The third semiconductor layer 133 includes a semiconductor material different from any of or at least one of those of the second semiconductor layer 132. The third semiconductor layer 133 may include GaN, and may or may not include AlGaN. The third semiconductor layer 133 may be an undoped layer or a layer doped with an impurity. The thickness of the third semiconductor layer 133 may be less than that of the first semiconductor layer 131.

The fourth semiconductor layer 134 may be disposed on the third semiconductor layer 133. The fourth semiconductor layer 134 may be disposed to have different thicknesses on the side surface and the bottom surface of the recess R. A thickness of the fourth semiconductor layer 134 disposed on the side surface of the recess R may be less than a thickness of the fourth semiconductor layer 134 disposed on the bottom surface of the recess R. The thickness of the fourth semiconductor layer 134 disposed on the side surface of the recess R may be greater than or equal to about 25 Å (2.5 nm) and less than or equal to about 150 Å (15 nm), and the thickness of the fourth semiconductor layer 134 disposed on the bottom surface of the recess R may be greater than or equal to about 50 Å (5 nm) and less than or equal to 300 Å (30 nm). The fourth semiconductor layer 134 includes the same semiconductor material as the second semiconductor layer 132, and may or may not include any material not included in the second semiconductor layer 132. The fourth semiconductor layer 134 includes a semiconductor material different from that of the first semiconductor layer 131. The fourth semiconductor layer 134 may include AlGaN. The fourth semiconductor layer 134 may be an undoped layer or a layer doped with an impurity, that may or may not be the same as any impurity doped in any other semiconductor layers.

Channels may be formed between the first semiconductor layer 131 and the second semiconductor layer 132, between the second semiconductor layer 132 and the third semiconductor layer 133, and between the third semiconductor layer 133 and the fourth semiconductor layer 134. The channels may be formed, for example, during operation of the semiconductor device 100. Accordingly, the channel layer 130 may include a plurality of channels. FIG. 1A shows that the first semiconductor layer 131, the second semiconductor layer 132, the third semiconductor layer 133, and the fourth semiconductor layer 134 form three channels, but the number of the channels is not limited thereto and may be two or more. For example, a fifth semiconductor layer (not shown) may be formed on the fourth semiconductor layer 134, and in this case, the semiconductor device 100 may include four channels. Also, for example, a sixth semiconductor layer (not shown) may be formed on the fifth semiconductor layer (not shown), and in this case, the semiconductor device 100 may include five channels. Also, for example, the semiconductor device 100 may not include the fourth semiconductor layer 134 and in this case, the semiconductor device 100 may include two channels.

The recess R has a bottom surface and an inclined side surface, and because the thicknesses of the second semiconductor layer 132, the third semiconductor layer 133, and the fourth semiconductor layer 134 disposed on the side surface of the recess R are less than the thicknesses of the second semiconductor layer 132, the third semiconductor layer 133, and the fourth semiconductor layer 134 disposed on the bottom surface of the recess R, the semiconductor device 100 may obtain a relatively high or high absolute value of a threshold voltage Vₜₕ. Through this, it may be possible to implement a device having a normally off characteristic. According to the normally off characteristic, in a gate-off state, for example, a normal state in which a voltage is not applied to a gate electrode GA, a channel is in an off state, and when a voltage is applied to the gate electrode GA, a channel is formed and the channel is in an on state.

The gate semiconductor layer 150 may be disposed on the fourth semiconductor layer 134. When the channel layer 130 includes only the first semiconductor layer 131, the second semiconductor layer 132, and the third semiconductor layer 133, the gate semiconductor layer 150 is disposed on the third semiconductor layer 133. The gate semiconductor layer 150 is located on the inclined side surface and the bottom surface of the recess R, and may be disposed to cover only a portion of an upper surface of the fourth semiconductor layer 134 or the third semiconductor layer 133 around the recess R. The gate semiconductor layer 150 may be a p-type semiconductor, such as polysilicon doped with a p-type impurity. The gate semiconductor layer 150 may include one or more materials selected from the Group III-V materials, e.g., nitrides including at least one of Al, Ga, and In. The gate semiconductor layer 150 may be AlₓIn_{y}Ga_{1-x-y}N(0≤x≤1, 0≤y≤1, x+y≤1). The gate semiconductor layer 150 may include at least one of GaN, InN, AlGaN, AlInN, InGaN, AlN, and AlInGaN, in single-crystalline and/or in polycrystalline phase. The gate semiconductor layer 150 may be doped with a p-type impurity such as magnesium (Mg) and/or born. For example, the gate semiconductor layer 150 may include p-type GaN. However, example embodiments are not limited thereto, and for example, the gate semiconductor layer 150 may be a p-AlGaN layer.

The gate semiconductor layer 150 may form a depletion region in the first semiconductor layer 131 and the third semiconductor layer 133. Due to the gate semiconductor layer 150, an energy band level of partial regions of the second semiconductor layer 132 and the fourth semiconductor layer 134 at positions facing the gate semiconductor layer 150 may be increased. A depletion region may be formed in a region of the first semiconductor layer 131 and the third semiconductor layer 133 facing the partial region of the second semiconductor layer 132 and the fourth semiconductor layer 134, the energy band level of which is increased by the gate semiconductor layer 150. The depletion region is or corresponds to a region in which a two-dimensional electron gas is not formed or has a lower electron concentration than other regions among the channel paths of the first semiconductor layer 131 and the third semiconductor layer 133.

A source SR and a drain DR may be formed to be spaced apart from each other on the channel layer 130. The source SR may be formed to be electrically connected to the channel layer 130 on one side of the channel layer 130, and the drain DR may be formed to be electrically connected to the channel layer 130 on another side of the channel layer 130. For example, the source SR and the drain DR may extend in a Z direction to contact all of the first semiconductor layer 131, the second semiconductor layer 132, the third semiconductor layer 133, and the fourth semiconductor layer 134. The source SR and the drain DR may make ohmic contact with the channel layer 130. The source SR and drain DR may include an electrically conductive material. The source SR and the drain DR may include, for example, a metal material and/or a doped semiconductor layer. A region of the channel layer 130 where the source SR and the drain DR contact may be doped with a concentration higher than other regions of the channel layer 130.

The gate semiconductor layer 150 may be positioned between the source SR and the drain DR and spaced apart from the source SR and the drain DR. The gate semiconductor layer 150 may have an energy band gap different from that of the channel layer 130.

The semiconductor device 100 may further include a passivation layer 160 covering the channel layers 130, 131, 140, and 141 and the gate semiconductor layer 150. The passivation layer 160 may include various types of insulating materials, for example, oxides such as one or more of SiO₂, HfOₓ, and Al₂O₃.

FIG. 1B is a schematic diagram illustrating an arrangement relationship between a source SR, a drain DR, and a recess R of the semiconductor device 100 according to various example embodiments.

Referring to FIG. 1B, the source SR and the drain DR may be spaced apart from each other in the X direction, and the recess R may be disposed between the source SR and the drain DR. The source SR, the drain DR, and the recess R may continuously extend along the Y direction. In addition, the gate semiconductor layer 150 may also have a shape continuously extending in the Y direction to cover the recess R.

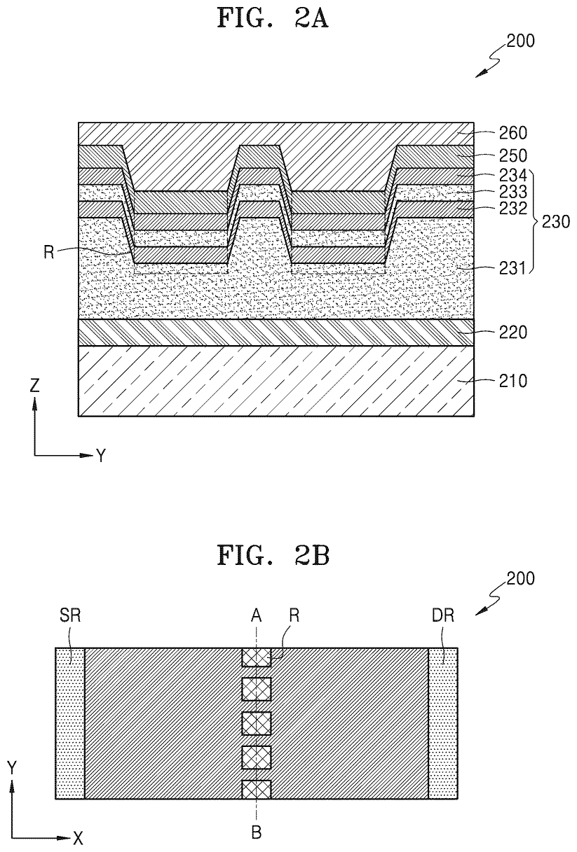

FIG. 2A is a cross-sectional view of a semiconductor device 200 according to another embodiment.

Referring to FIGS. 2A and 2B, the semiconductor device 200 includes a first semiconductor layer 231, a second semiconductor layer 232, a third semiconductor layer 233, a fourth semiconductor layer 234, and a gate semiconductor layer 250. The first semiconductor layer 231, the second semiconductor layer 232, the third semiconductor layer 233, and the fourth semiconductor layer 234 may be expressed as a channel layer 230. A buffer layer 220 may be provided on the substrate 210, and the channel layer 230 may be formed on the buffer layer 220.

FIG. 2A is a partial cross-sectional view taken along line A-B of FIG. 2B. In the description of FIGS. 2A and 2B, descriptions previously given with reference to FIGS. 1A and 1B will be omitted.

The first semiconductor layer 231 may include a plurality of recesses R arranged at intervals in the Y direction perpendicular to the X direction. The plurality of recesses R may be disposed apart from adjacent recesses R by greater than or equal to about 100 nm and less than or equal to about 1 μm. The first semiconductor layer 231 may be the same as the first semiconductor layer 131 of FIG. 1A except for the fact that the first semiconductor layer 231 includes a plurality of recesses R. Although two recesses R are shown in FIG. 2A and five recesses R are shown in FIG. 2B, the number of recesses R is not limited thereto, and the number of recesses may be two or more, e.g. five or more.

The gate semiconductor layer 250 may extend in the Y direction to cover the plurality of recesses R. Accordingly, three sides of the channel layer 230 between the plurality of recesses R may be surrounded by the gate semiconductor layer 250. An upper surface of a protruding portion between adjacent recesses and inclined both side surfaces of the channel layer 230 between the plurality of recesses R may be surrounded by the gate semiconductor layer 250. The channel layer 230 between the plurality of recesses R may be gate driven from three sides. Using this, a structure similar to a tri-gate may be formed.

Ions may be implanted into a region where the recess R is present. Ions to be implanted may be, for example, one or more of Ar, F, B, or Mg. Ions may be implanted with a beamline implantation process and/or with a plasma assisted ion doping (PLAID) process. The channel layer 230 under the recess R, which may be difficult to cover on three sides, may be blocked, or at least partially blocked or shadowed, by implantation with ions. An ion implantation region may extend from the gate semiconductor layer 250 at the bottom of each recess R to the top of the first semiconductor layer 231 in the Z direction. Through this, a gate may be more easily controlled.

FIG. 2B is a schematic diagram illustrating a disposition relationship between a source SR, a drain DR, and a recess R of a semiconductor device 200 according to various example embodiments.

Referring to FIG. 2B, the source SR and the drain DR may be spaced apart from each other in the X direction, and a plurality of recesses R may be disposed between the source SR and the drain DR. The plurality of recesses R may be arranged at intervals in the Y direction perpendicular to the X direction between the source SR and the drain DR. The source SR and the drain DR may continuously extend in the Y direction. In addition, the gate semiconductor layer 250 may also have a shape continuously extending in the Y direction to cover the recesses R.

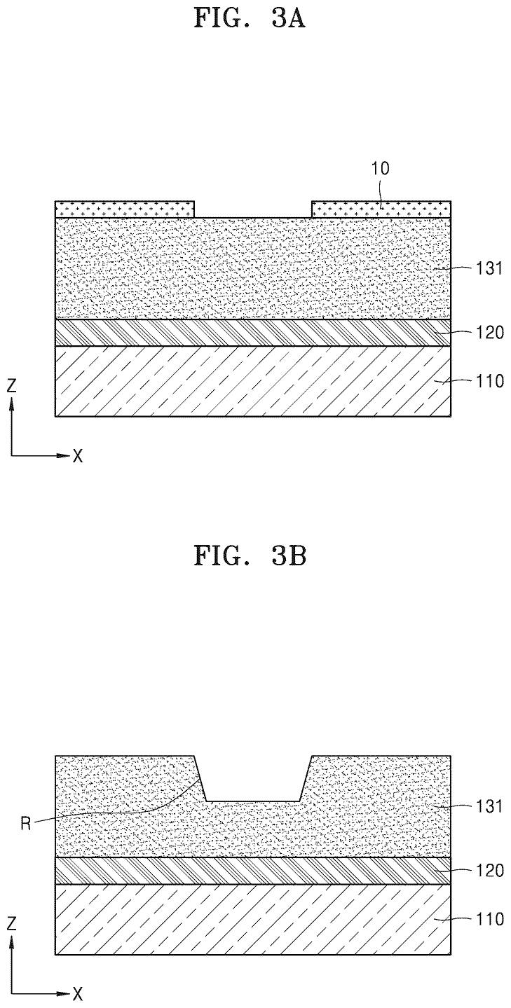

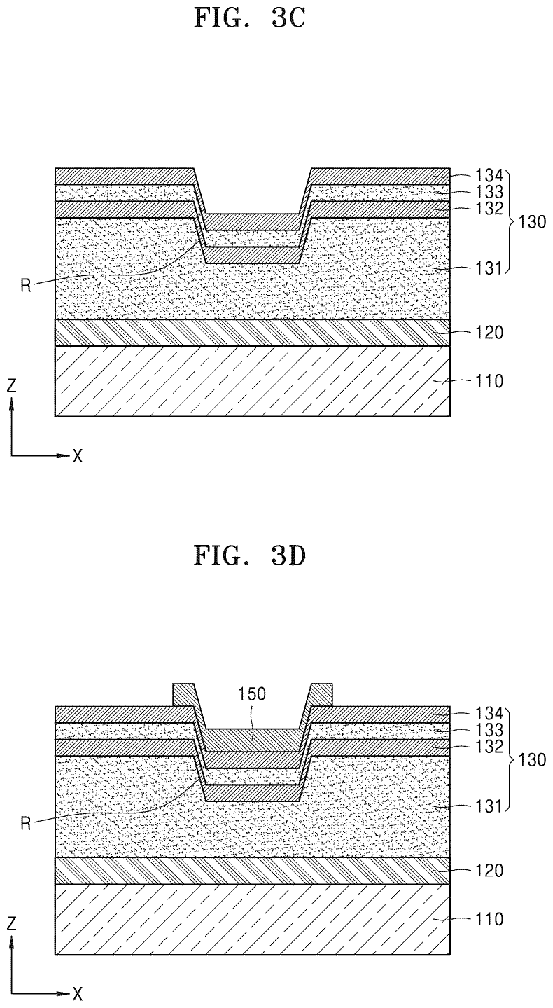

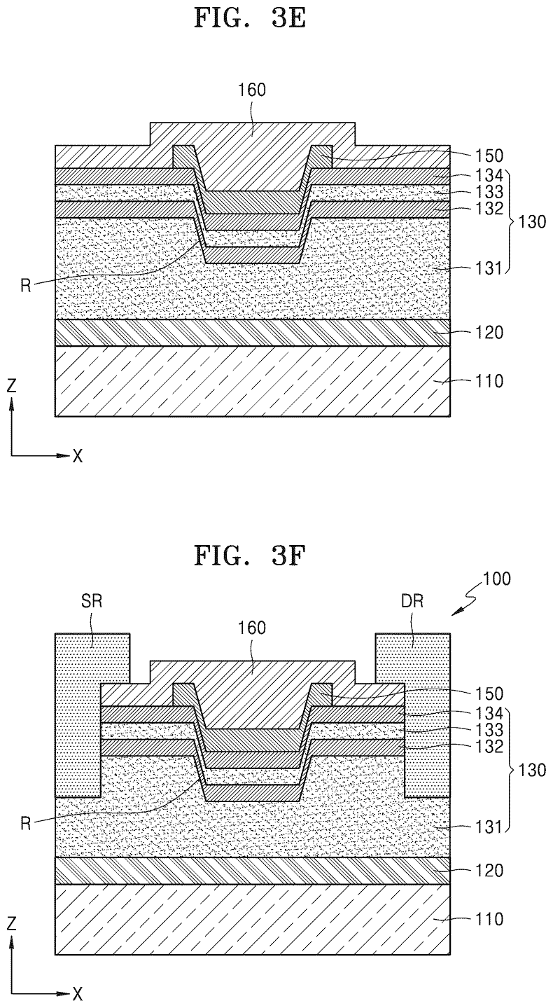

FIGS. 3A to 3F are cross-sectional views illustrating a method of manufacturing a semiconductor device according to various example embodiments.

Referring to FIG. 3A, a buffer layer 120 and a first semiconductor layer 131 are sequentially formed on a substrate 110. The substrate 110, the buffer layer 120, and the first semiconductor layer 131 may be the same as the substrate 110, the buffer layer 120, and the first semiconductor layer 131 of FIG. 1A. The buffer layer 120 may be omitted, for example, when a difference in lattice constant between the material of the substrate 110 and a channel layer is sufficiently small,. A mask layer such as photoresist layer 10 may be formed on the first semiconductor layer 131. A hard mask layer may be patterned to fit a width of a recess R through a photolithography process using the photoresist layer 10. Thereafter, as shown in FIG. 3B, the recess R may be formed by etching (or at least partially etching) the first semiconductor layer 131 using the patterned hard mask layer. In some example embodiments, a portion of the first semiconductor layer 131 may not be fully etched, and a top of the buffer layer 120 may not be exposed during etching of the first semiconductor layer 131.

Referring to FIG. 3C, a second semiconductor layer 132, a third semiconductor layer 133, and a fourth semiconductor layer 134 are sequentially formed on the first semiconductor layer 131. The second semiconductor layer 132, the third semiconductor layer 133, and the fourth semiconductor layer 134 may be the same as the second semiconductor layer 132, the third semiconductor layer 133, and the fourth semiconductor layer 134 of FIG. 1A. The fourth semiconductor layer 134 may be omitted. In some example embodiments, each of the second semiconductor layer 132, the third semiconductor layer 133, and the fourth semiconductor layer 134 may be formed with the same or different processes, in-situ or in different chambers, with processes such as but not limited to one or more of chemical vapor deposition (CVD), physical vapor deposition (PVD), or atomic layer deposition (ALD).

Referring to FIG. 3D, a gate semiconductor layer 150 is formed on the fourth semiconductor layer 134. The gate semiconductor layer 150 may be the same as the gate semiconductor layer 150 of FIG. 1A. For example, after depositing a material of the gate semiconductor layer 150 on an upper surface of the fourth semiconductor layer 134, the gate semiconductor layer 150 may be formed by removing a material of the gate semiconductor layer 150 other than the recess R and its surroundings through etching. The gate semiconductor layer 150 may be formed with one or more of chemical vapor deposition (CVD), physical vapor deposition (PVD), or atomic layer deposition (ALD).

Referring to FIG. 3E, a passivation layer 160 covering the fourth semiconductor layer 134 and the gate semiconductor layer 150 is formed. The passivation layer 160 may include various types of insulating materials, for example, oxides such as one or more of SiO₂, HfOₓ, Al₂O₃, etc.

Referring to FIG. 3F, a source SR and a drain DR that pass through the passivation layer 160 and contact the channel layer 130 are formed. The source SR and the drain DR may contact both sides of the channel layer 130, respectively. For example, the fourth semiconductor layer 134, the third semiconductor layer 133, and the second semiconductor layer 132 are etched to partially expose the first semiconductor layer 131, and the source SR and the drain DR may be formed by filling the etched portion with a material of the source SR and the drain DR.

The semiconductor device manufactured in this way may be substantially the same as the semiconductor device 100 described with reference to FIGS. 1A and 1B.

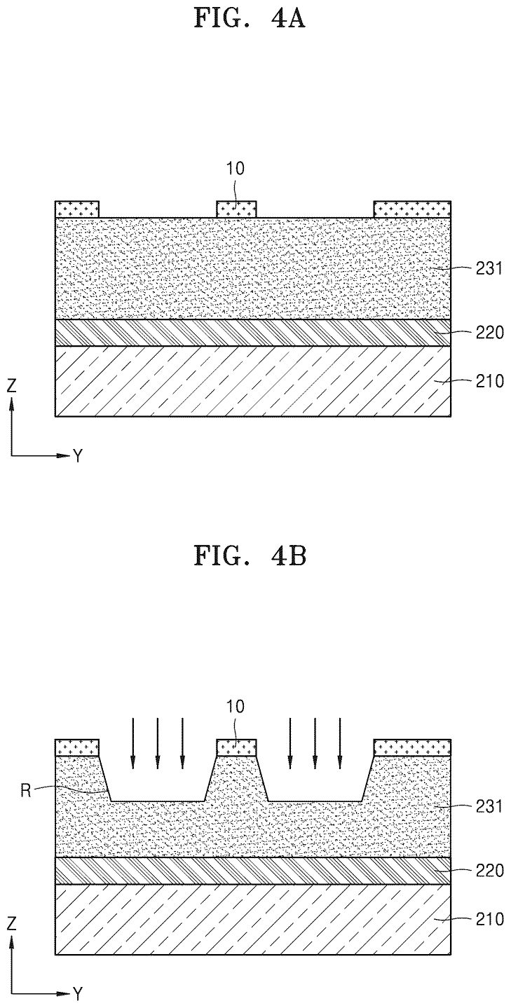

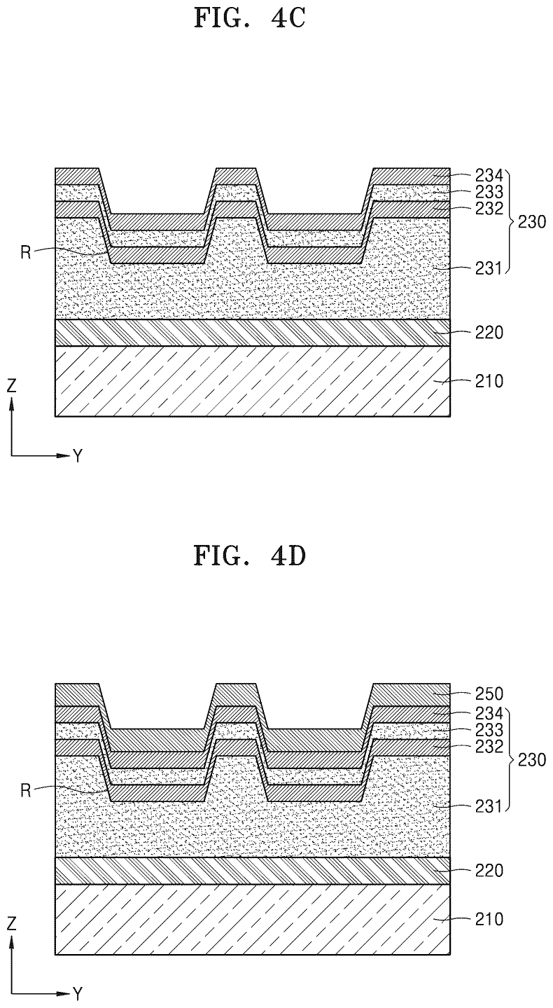

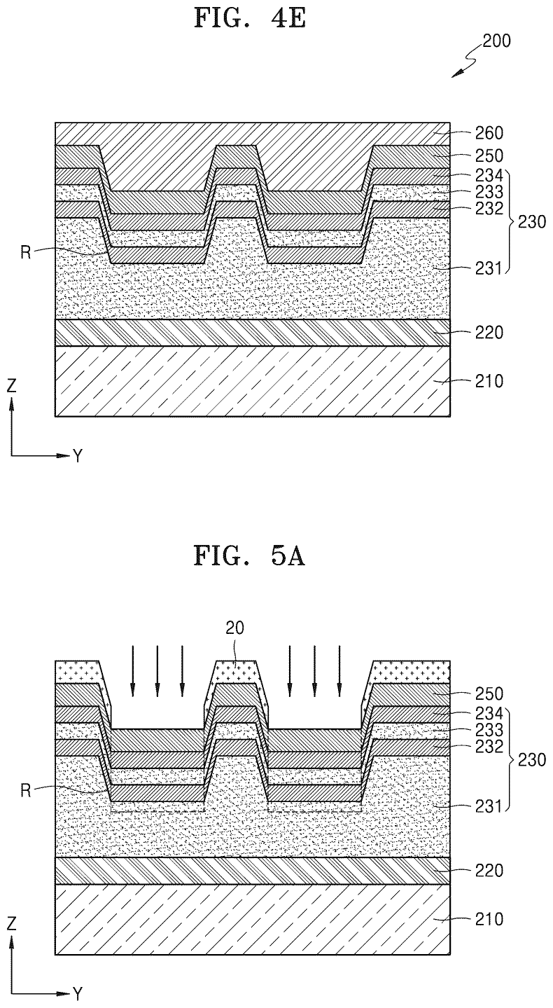

FIGS. 4A to 4E are diagrams illustrating a method of manufacturing a semiconductor device according to various example embodiments.

Referring to FIG. 4A, a buffer layer 220 and a first semiconductor layer 231 are sequentially formed on a substrate 210. The substrate 210, the buffer layer 220, and the first semiconductor layer 231 may be the same as the substrate 210, the buffer layer 220, and the first semiconductor layer 231 of FIG. 2A. The buffer layer 220 may be omitted, for example, when a difference in lattice constant between the material of the substrate 210 and the channel layer is sufficiently small. A mask layer such as a photoresist layer 10 may be formed on the first semiconductor layer 231. A hard mask layer may be patterned to fit a width of the recess R through a photolithography process using the photoresist layer 10. Thereafter, as shown in FIG. 4B, the first semiconductor layer 231 may be etched (anisotropically and/or isotropically) by using the patterned hard mask layer to form a plurality of recesses R arranged at intervals in the Y direction.

Referring to FIG. 4C, a second semiconductor layer 232, a third semiconductor layer 233, and a fourth semiconductor layer 234 are sequentially formed on the first semiconductor layer 231. The second semiconductor layer 232, the third semiconductor layer 233, and the fourth semiconductor layer 234 may be the same as the second semiconductor layer 232, the third semiconductor layer 233, and the fourth semiconductor layer 234 of FIG. 2A.

Referring to FIG. 4D, a gate semiconductor layer 250 is formed on the fourth semiconductor layer 234. The gate semiconductor layer 250 may be the same as the gate semiconductor layer 250 of FIG. 2A. The gate semiconductor layer 250 may surround three surfaces of the fourth semiconductor layer 234. The gate semiconductor layer 250 may have a tri-gate structure. Through this, a gate driving in three planes is possible.

Referring to FIG. 4E, a passivation layer 260 covering the fourth semiconductor layer 234 and the gate semiconductor layer 250 is formed. The passivation layer 260 may include various types of insulating materials, for example, oxides such as SiO₂, HfOₓ, Al₂O₃, etc.

The semiconductor device manufactured in this way may be substantially the same as the semiconductor device 200 described with reference to FIGS. 2A and 2B.

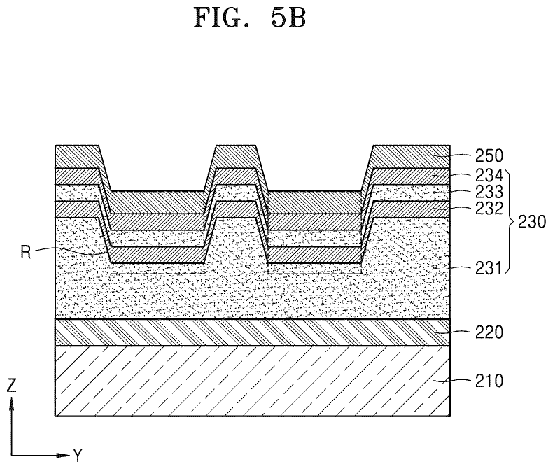

FIGS. 5A and 5B are diagrams illustrating a method of manufacturing a semiconductor device according to another embodiment.

The operations of FIGS. 5A and 5B may be inserted between the operations of FIGS. 4D and 4E.

Referring to FIG. 5A, a photoresist layer 20 may be formed on the gate semiconductor layer 250. The photoresist layer 20 may not be formed on an upper portion of the gate semiconductor layer 250 that perpendicularly corresponds to the bottom surface of the recesses R. For example, the photoresist layer 20 may be formed only on the upper portion of the gate semiconductor layer 250 corresponding to the inclined side surface of each of the recesses R and the protruding portion between two adjacent recesses R. The channel layer 230 may be blocked or shadowed by implanting ions into a portion where the photoresist layer 20 is not formed. For example, the ion implantation region may be formed by implanting ions from the gate semiconductor layer 250 into the upper portion of the first semiconductor layer 231 at the bottom surface of the recess R. Through this, a gate may be more easily controlled. Thereafter, as shown in FIG. 5B, the photoresist layer 20 may be removed.

According to the semiconductor device and the method of manufacturing the same according to the embodiments, a channel is formed after forming a recess, and thus, the occurrence of a trap site may be minimized or reduced in likelihood of occurrence and/or in impact from occurrence, thereby making a semiconductor device with improved reliability.

Therefore, according to various example embodiments, it may be observer or confirmed that a semiconductor device with reduced occurrence of trap sites and/or a method of manufacturing the semiconductor device may be provided. Although semiconductor devices and methods of manufacturing the semiconductor devices have been described with reference to the embodiments shown in the drawings. However, it will be understood by those of ordinary skill in the art that various changes in form and details may be made thereto without departing from the spirit and scope of the disclosure. Therefore, embodiments should be considered in descriptive sense only and not for purposes of limitation. The scope of the disclosure is defined not by the detailed description of the disclosure but by the appended claims, and all differences within the scope will be construed as being included in the disclosure.

It should be understood that various embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims.

What is claimed is:

1. A method of manufacturing a semiconductor device, the method comprising:
forming a first semiconductor layer on a substrate;
forming a recess by at least partially etching the first semiconductor layer;
sequentially forming a second semiconductor layer and a third semiconductor layer on the first semiconductor layer in which the recess is formed; and
forming a source and a drain respectively in contact with a first and a second side of the first semiconductor layer, the second semiconductor layer, and the third semiconductor layer.

2. The method of claim 1, wherein
the source and drain are spaced apart from each other in a first direction, and
the forming of the recess includes forming a plurality of recesses arranged at intervals in a second direction perpendicular to the first direction, the plurality of recess between the source and the drain.

3. The method of claim 2, further comprising:
implanting ions into the recess.

4. The method of claim 3, wherein the ions include at least one of Ar, F, B, or Mg.

5. The method of claim 2, wherein the plurality of recesses are formed spaced apart from adjacent recesses by greater than or equal to about 100 nm and less than or equal to about 1 μm.

6. The method of claim 1, wherein
the recess has a bottom surface and an inclined side surface, and
a thickness of the second semiconductor layer disposed on the side surface of the recess is less than the thickness of the second semiconductor layer disposed on the bottom surface of the recess.

7. The method of claim 1, wherein, in the forming of the recess, a shape of the recess is formed into at least one of an inverted trapezoid, a V-shape or a U-shape.

8. The method of claim 1, further comprising:
forming a fourth semiconductor layer on the third semiconductor layer.

9. The method of claim 8, further comprising:
forming a gate semiconductor layer on the fourth semiconductor layer.

10. The method of claim 9, further comprising:
forming a passivation layer covering the fourth semiconductor layer and the gate semiconductor layer.

11. The method of claim 9, wherein the gate semiconductor layer includes p-type GaN.

12. A semiconductor device comprising:
a substrate;
a first semiconductor layer on the substrate and defining a recess;
a second semiconductor layer on the first semiconductor layer;
a third semiconductor layer on the second semiconductor layer;
a gate semiconductor layer on the third semiconductor layer; and
a source and a drain respectively contacting first and second sides of the first semiconductor layer, the second semiconductor layer, and the third semiconductor layer,
wherein a channel is between the first semiconductor layer and the second semiconductor layer and between the second semiconductor layer and the third semiconductor layer.

13. The semiconductor device of claim 12, wherein
the source and the drain are spaced apart from each other in a first direction, and
the first semiconductor layer includes a plurality of recesses arranged at intervals in a second direction perpendicular to the first direction, between the source and the drain.

14. The semiconductor device of claim 13, wherein the gate semiconductor layer has a tri-gate structure.

15. The semiconductor device of claim 13, wherein the plurality of recesses are apart from adjacent recesses by greater than or equal to about 100 nm and less than or equal to about 1 μm.

16. The semiconductor device of claim 12, further comprising:
a source and a drain respectively in contact with first and second sides of the first semiconductor layer, the second semiconductor layer, and the third semiconductor layer.

17. The semiconductor device of claim 12, wherein
the recess has a bottom surface and an inclined side surface, and
a thickness of the second semiconductor layer on a side surface of the recess is less than a thickness of the second semiconductor layer on a bottom surface of the recess.

18. The semiconductor device of claim 12, wherein a shape of the recess has at least one of an inverted trapezoid, a V-shape or a U-shape.

19. The semiconductor device of claim 12, further comprising:
a fourth semiconductor layer between the third semiconductor layer and the gate semiconductor layer.

20. The semiconductor device of claim 12, further comprising:
a passivation layer covering the third semiconductor layer and the gate semiconductor layer.
